(19) United States
(12) Patent Application Publication
(10) Pub. No.: US 2017/0359903 A1
(43) Pub. Date: Dec. 14, 2017

(54) Method and System for Processing a Circuit Substrate

(71) Applicant: Christopher Lee Bohler, Peachtree City, GA (US)

(72) Inventor: Christopher Lee Bohler, Peachtree City, GA (US)

(21) Appl. No.: 15/181,832

(22) Filed: Jun. 14, 2016

(51) Int. Cl. H05K 3/12

(52) U.S. Cl. CPC H05K 3/1216

(57) ABSTRACT

An array of ultraviolet light emitting diodes can cure ultraviolet curable material, such as solder mask or ink, that has been applied to a substrate in connection with fabricating electronic circuit devices. The substrate can be placed in a housing associated with a processing station of a manufacturing operation. A mask or stencil can be positioned adjacent the substrate. The ultraviolet curable material can be applied to the substrate via the mask or stencil, for example using a squeegee. The ultraviolet light emitting diodes can be moved over the substrate to cure the ultraviolet curable material. The substrate with the cured material can be removed from the housing.

### STATEMENT REGARDING FEDERALLY SPONSORED RESEARCH OR DEVELOPMENT

This invention was made with government support under Contract Number DE_EE0006260 awarded by the United States Department of Energy. The government has certain rights in the invention.

### TECHNICAL FIELD

The present disclosure relates generally to fabricating circuitry, and more particularly to utilizing ultraviolet (UV) light emitting diodes (LEDs) for curing materials in connection with patterning or printing substrates, such as circuit boards.

### BACKGROUND

Conventional approaches to manufacturing electronic circuit devices typically entail transferring a work piece along a substantial path of multiple machines and processes, each performing a discrete task. For example, a series of separate stations may be utilized to print labels and solder mask on a circuit substrate, and to cure the applied materials. The curing equipment typically operates using sources of curing energy that are large and unwieldy and that are so inefficient as to present heat dissipation issues.

Accordingly, improved technologies for manufacturing electronic circuit devices are needed. For example, need exists for compact and efficient sources of curing energy. Further need exists for workstations, machines, and processes that are compact, integrated, or offer other advantages. A capability addressing such a need, or some related deficiency in the art, would support improved fabrication of electronic circuit devices, including circuit substrates.

### SUMMARY

In one aspect of the disclosure, an array of ultraviolet light emitting diodes can cure ultraviolet curable material, such as solder mask or ink, that has been printed, screened, or otherwise applied to a substrate in connection with fabricating circuit devices. The array of ultraviolet light emitting diodes can be compact and efficient so that inks and solder masks can be printed and cured at one fabrication station, for example in a housing or enclosure on a circuit production line.

The foregoing discussion of applying and curing materials on a substrate is for illustrative purposes only. Various aspects of the present disclosure may be more clearly understood and appreciated from a review of the following text and by reference to the associated drawings and the claims that follow. Other aspects, systems, methods, features, advantages, and objects of the present disclosure will become apparent to one with skill in the art upon examination of the following drawings and text. It is intended that all such aspects, systems, methods, features, advantages, and objects are to be included within this description and covered by this application and by the appended claims of the application.

### BRIEF DESCRIPTION OF THE DRAWINGS

FIG. 1 is a functional block diagram of a system for manufacturing electronic circuit devices in accordance with some example embodiments of the present disclosure.

FIG. 2 is a functional schematic of a processing station for applying materials to a substrate and curing the materials in connection with manufacturing electronic circuit devices in accordance with some example embodiments of the present disclosure.

FIG. 3 is flowchart of a process for applying materials to a substrate and curing the materials in connection with manufacturing electronic circuit devices in accordance with some example embodiments of the present disclosure.

Many aspects of the disclosure can be better understood with reference to the above drawings. The elements and features shown in the drawings are not necessarily to scale, emphasis being placed upon clearly illustrating the principles of exemplary embodiments of the present disclosure. Moreover, certain dimensions may be exaggerated to help visually convey such principles.

### DESCRIPTION OF EXAMPLE EMBODIMENTS

Some example embodiments of the present disclosure will be discussed in further detail below with reference to the figures. However, the present technology can be embodied in many different forms and should not be construed as limited to the embodiments set forth herein. Rather, these embodiments are provided so that this disclosure will be thorough and complete, and will fully convey the scope of the disclosure to those having ordinary skill in the art. Furthermore, all “examples,” “embodiments,” “example embodiments,” or “exemplary embodiments” given herein are intended to be non-limiting and among others supported by representations of the present technology.

Some of the embodiments may comprise or involve processes that will be discussed below. Certain steps in such processes may naturally need to precede others to achieve intended functionality or results. However, the technology is not limited to the order of the steps described to the extent that reordering or re-sequencing does not render the processes useless or nonsensical. Thus, it is recognized that some steps may be performed before or after other steps or in parallel with other steps without departing from the scope and spirit of this disclosure.

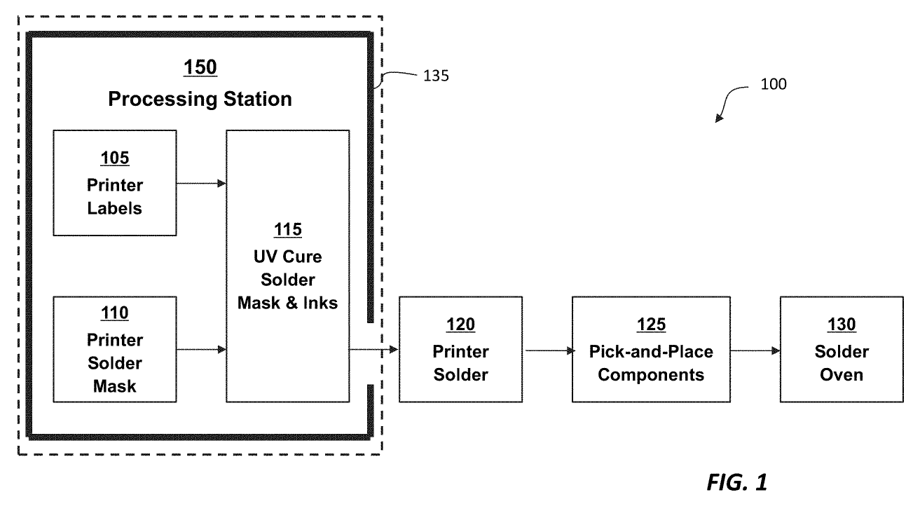

Turning now to FIG. 1, this figure illustrates a functional block diagram of an example system 100 for manufacturing electronic circuit devices according to some embodiments of the present disclosure. In the illustrated embodiment, the system 100 can produce circuit boards populated with electronic components, for example.

As illustrated, the system 100 comprises a processing station 150 that outputs work pieces to a print solder unit 120. The processing station 150 can comprise a housing 135 that provides an enclosure for processing the work pieces. The work pieces can comprises circuit boards or other circuit substrates, for example. The print solder unit 120 outputs work pieces to a pick-and-place unit 125. The pick-and-place unit 125, in turn, outputs work pieces to a solder oven 130, for work piece completion.

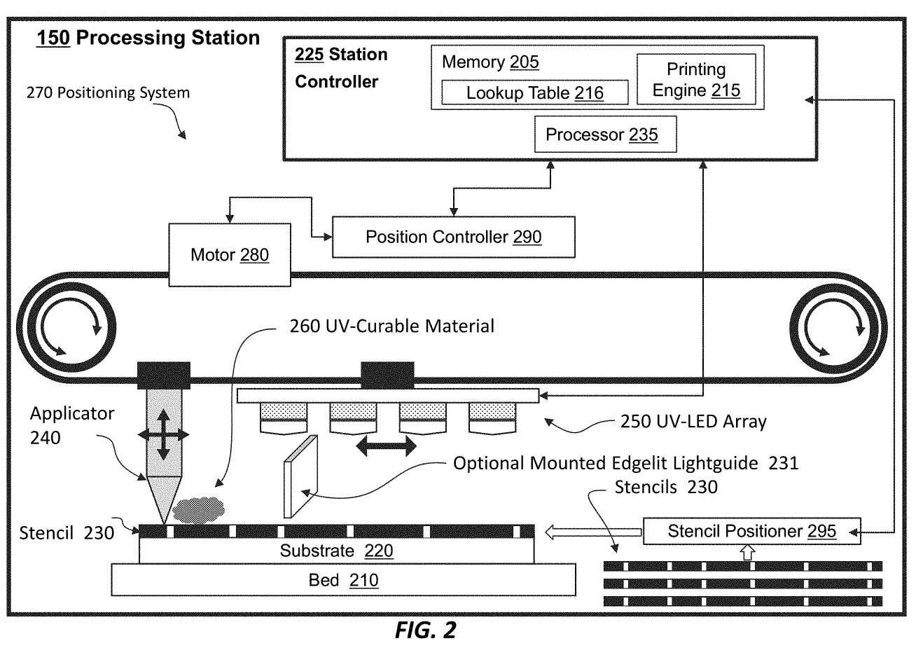

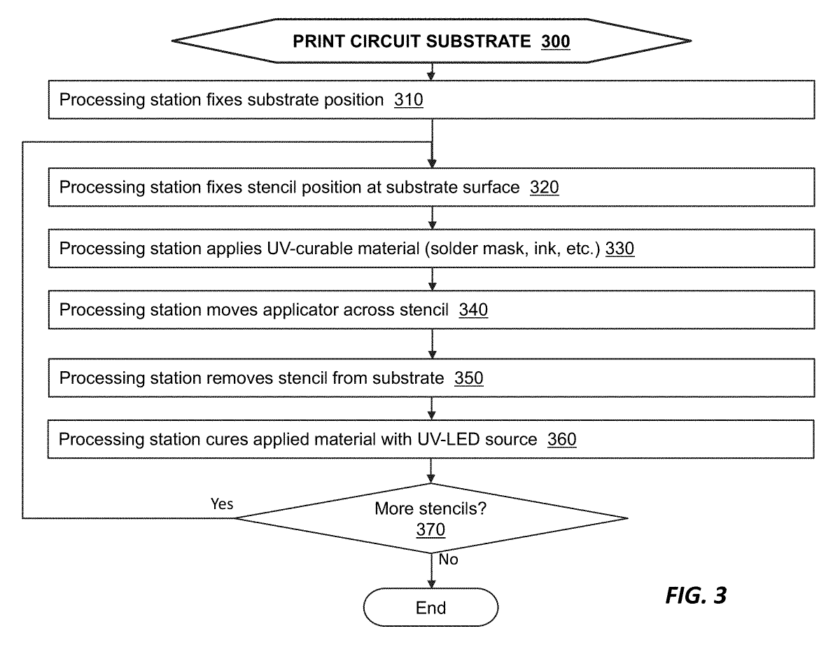

As will be discussed in further detail below with reference to FIGS. 2 and 3, the processing station 150 comprises a printer label capability 105 and a printer solder mask capability 110 for applying ultraviolet curable materials to a circuit substrate. The circuit substrate can comprise a circuit board, for example.

The printer label capability 105 can apply labels to the circuit substrate, for example text, codes, letters, information, or indicia. Meanwhile, the printer solder mask capability 110 can apply solder masks to the circuit substrate. The labels and solder mask can comprise ultraviolet curable materials.

The example processing station 150 further comprises an ultraviolet cure capability 115. In an example embodiment, the ultraviolet cure capability 115, the printer label capability 105, and the printer solder mask capability 110 are enclosed in the housing 135 of the processing station 150.

As will be discussed in further detail below, an example embodiment of the ultraviolet cure capability 115 comprises an array of light emitting diodes (or one or more ultraviolet laser diodes) that emit ultraviolet light of sufficient intensity and appropriate wavelength to cure the applied materials.

Accordingly, the processing station 150 can output circuit substrates with cured labels and solder masks, for receipt by the printer solder unit 120. The printer solder unit 120 applies solder to each circuit substrate, with the solder mask defining regions on the circuit substrate where the solder adheres to the circuit substrate. For example, the solder mask may define solder pads where electronic components are to be soldered to the circuit substrate.

The pick-and-place unit 125 receives the circuit substrate from the printer solder unit 120. The pick-and-place unit 125 populates the circuit substrate with electronic components, for example capacitors, resistors, chips, light emitting diodes, transistors, and other appropriate devices. An example embodiment of the pick-and-place unit 125 can comprise a vision system and robotic arm or other appropriate technology for populating the circuit substrate.

The populated circuit substrate transfers from the pick-and-place unit 125 to the solder oven 130. The solder oven 130 heats the populated circuit substrate, including the applied solder. When the heated solder cools, the electronic components are fully attached and soldered to the circuit substrate, and the system 100 outputs a completed work piece, specifically a circuit board.

Turning now to FIG. 2, this figure illustrates a functional schematic of an example processing station 150 for applying materials 260 to a circuit substrate 220 and curing the materials 260 in connection with manufacturing electronic circuit devices according to some embodiments of the present disclosure. The processing station 150 illustrated in FIG. 2 represents an example embodiment of the processing station 150 illustrated in FIG. 1, and will be discussed below as such an example without limitation. As described above with reference to FIG. 1, the elements of the processing station 150 that are illustrated in FIG. 2 can be sufficiently compact and energy efficient to be disposed within the housing 135 (illustrated in FIG. 1).

The processing station 150 comprises a bed 210 that supports the circuit substrate 220. A stencil positioner 295, which is under control by a station controller 225, transfers stencils 295 onto and off of the circuit substrate 220. The stencil positioner 295 can comprise a robotic arm or other appropriate mechanized device, for example.

An applicator 240 applies ultraviolet curable material 260 to the stencil 230, and thus to defined areas of the circuit substrate. The ultraviolet curable materials 260 can comprise labeling inks, solder mask materials, or other appropriate materials. In an example embodiment, the applicator 240 comprises one or more fluid reservoirs for the ultraviolet curable materials 260 and one or more squeegees for spreading the materials. In various embodiments, the applicator 240 can comprise an inkjet printer, a screen-printing system, a rotogravure system (“gravure”), or other appropriate dispenser, to mention s few representative examples without limitation.

A positioning system 270 moves the applicator 240 across the circuit substrate 220 to spread the ultraviolet curable materials 260. As illustrated and discussed below, the positioning system 270 can comprise a computer-controlled positioning system. Once an ultraviolet curable material 260 is spread, an array of ultraviolet light emitting diodes 250 emits ultraviolet light to cure the material 260. The positioning system 270 can also move the array of ultraviolet light emitting diodes 250 across the circuit substrate 220. In various example embodiments, the positioning system 270 can provide scanning motion in one dimension, two dimensions, or three dimensions.

In some example embodiments, the array of ultraviolet light emitting diodes 250 is a one-dimensional array, so that the light emitting diodes 250 are arranged in a single row. In some example embodiments, the array of light emitting diodes 250 is a two-dimensional array, so that the light emitting diodes 250 extend in two perpendicular directions.

In some embodiments, ultraviolet light output by a one- or two-dimensional array of light emitting diodes 250 couples into one edge of a panel-shaped lightguide 231 that can be characterized as an edgelit lightguide. The panel-shaped lightguide 231 can comprise a rectangular plate of optical material that has two major faces and four edges that form a rectangular perimeter with respect to the major faces, for example. The coupled ultraviolet light propagates in the panel-shaped lightguide 231 from the input lightguide edge towards the opposing lightguide edge via total internal reflection off of the major faces of the panel-shaped lightguide 231. The ultraviolet light then emits from the panel-shaped lightguide 231 through that opposing edge. The panel-shaped lightguide 231 can effectively blend or homogenize the ultraviolet light so that the light emits in a uniform rectangular format that corresponds to the lightguide edge, rather than as from an array of discrete sources. In such an embodiment, the panel-shaped lightguide 231 can be mounted in a fixed vertical orientation, and the circuit substrate 220 can be moved linearly (for example as if on a conveyor belt) under the light-emitting edge of the panel-shaped lightguide 231. The ultraviolet light emitting diodes 250 can then be turned on and off in synchronization with motion of the circuit substrate 220, to apply ultraviolet light to specified locations of the circuit substrate 220. Thus, the station controller 225 can coordinate discrete linear movements (or continuous linear motion) of the circuit substrate 220 and firing of the light emitting diodes 250. Alternatively, in some embodiments, the light emitting diodes 250 may remain while potentially being dimmed via pulse width modulation or other appropriate technique. Some embodiments that utilize a panel-shaped lightguide 231 for delivering curing ultraviolet light can be viewed as providing a “frame-shot” ultraviolet cure, as an alternative to a “rastering” ultraviolet cure, for example.

In some embodiments, one or more ultraviolet laser diodes are utilized for the light source, for example to achieve a rapid cure rate. The ultraviolet laser diode(s) may further output energy in a relatively narrow wavelength range. In some embodiments, the ultraviolet laser diode light source is mounted in a fixed position. A mirror system can receive a beam of ultraviolet light from the fixed-position, ultraviolet light source. The mirror system can then move and direct the beam of light onto the circuit substrate 220 or other part to be cured. Accordingly, in some embodiments, the positioning system 270 moves a mirror while receiving a beam of light from a light source that is mounted in a fixed position.

In the illustrated embodiment, the station controller 225 controls position and operation of the applicator 240 and the array of ultraviolet light emitting diodes 250. The station controller 225 can switch the light emitting diodes 250 off and on as well as controlling intensity via dimming.

In some example embodiments, the station controller 255 further controls spectral content and intensity of the light emitted by the array of ultraviolet light emitting diodes 250. Spectral content can be controlled by including light emitting diodes 250 of differing spectral outputs in the array and then activating the light emitting diodes 250 in the array that will produce a desired wavelength range of light, for example. Additionally, the light emitting diodes 250 in the array can be individually dimmed. Accordingly, the light emitting diodes 250 can be individually addressable to deliver light having precisely controlled intensity, wavelength, and position.

In this manner, the output intensity and spectral content of the curing illumination can be selected according to the type material being cured. Black ink typically exhibits a different absorption spectrum than white ink, and the curing illumination can be selected and delivered to match the absorption spectrum of each ink. As another example, the inks (and other curable materials) of different manufacturers may react differently to different wavelengths and intensities of curing light, and the curing light can be adjusted to match each manufacturer's ink parameters and formulation.

In some example embodiments, the station controller 225 comprises memory 205 or a database for storing operating parameters for the array of light emitting diodes 250, or may access such a database from a remote server or other site. The database can comprise a lookup table 216 that associates inks and other curable materials with specified wavelengths and intensities for the curing light. An operator of the station controller 225 can make an entry that specifies the ink. The station controller 225 can then query the database and the lookup table 216 to provide the desired wavelengths and intensity for the specified ink. The station controller 225 can then control the array of light emitting diodes 250 to deliver optimized wavelength ranges and intensities of curing light according to information in the lookup table 216.

In some example embodiments, the spectral content and intensity of the curing light is determined empirically, and the resulting information can then be stored in the lookup table 216. For example, the processing station 150 can run the circuit substrate 220 (or a mockup of the circuit substrate 220) with different inks and different intensities and wavelengths of the curing light until desired or optimized parameters are obtained.

In some example embodiments, the intensity and wavelength parameters can be adjusted on the fly. That is, the processing station 150 can adjust intensity and wavelength during production operations. The real-time adjustments can refine or improve production output, yield, cure rate, or cure quality, for example. In some example embodiments, the processing station 150 can refine the curing parameters by scanning a broadband light emitting diode array while measuring the amount of absorption across a spectral range for the inks applied to the circuit substrate 220. The intensity and wavelength output by the array of light emitting diodes 250 can then be controlled dynamically according to the absorption feedback, for example. Accordingly, some embodiments of the processing station 150 can comprise a feedback control loop in which light intensity and/or light wavelength is controlled according to cure monitoring.

To position the applicator 240 and the array of ultraviolet light emitting diodes 250, the station controller 225 interfaces with a position controller 290 that in turn interfaces with a motor 280, for example a stepper or linear motor.

In the illustrated embodiment, the station controller 225 comprises a processor 235, memory 205, and a printing engine 215 stored in the memory 205 and executed by the processor 235. In some example embodiments, the processor 235 can comprise one or more microprocessors, microcontrollers, programmable logic controllers, personal computers, or other appropriate computing systems.

Example embodiments of the memory 205 can comprise volatile and nonvolatile memory, such as random access memory (RAM) and flash memory for example. In an example embodiment, the memory 205 can comprise firmware for executing management and control functions. For example, the memory 205 can comprise persistent memory that stores program code, including the printing engine 215. An example embodiment of the printing engine 215 can comprise computer executable instructions for implementing the process 300 that is illustrated in flowchart form in FIG. 3 and discussed below.

Turning now to FIG. 3, this figure illustrates a flowchart of an example process for applying materials 260 to the circuit substrate 220 and curing the materials 260 in connection with manufacturing electronic circuit devices according to some embodiments of the present disclosure. Process 300 can comprise an example embodiment of the printing engine 215 that is illustrated in FIG. 2, for example.

In some example embodiments, instructions for execution of process 300 (or a portion thereof) can be stored in the memory 205 and executed by the processor 235 of the station controller 225. For example, process 300 can be practiced using instructions that are provided in the printing engine 215 or in some other appropriate location or locations. Recognizing that the process 300 can be implemented or practiced in various places and in various forms, the process 300 will be discussed below with reference to an embodiment in which instructions are stored in the memory 205 as the printing engine 215, without limitation.

At block 310 of the process 300, the processing station 225 positions the circuit substrate 220 on the bed 210. The circuit substrate 220 may be positioned by a robotic arm or by the positioning system 270, for example.

At block 320, the stencil positioner 295 places a stencil 295 on the circuit substrate 220.

At block 330, the applicator 240 applies ultraviolet curable material 260 at the stencil 295.

At block 340, the positioning system 270 moves the applicator 240 across the stencil 295 to spread the ultraviolet curable material 260. In an example embodiment, the positioning system 270 spreads the material 260 using a squeegee.

At block 350, the stencil positioner 295 lifts and removes the stencil 230 from the circuit substrate 220.

At block 360, the array of ultraviolet light emitting diodes 250 emits ultraviolet light to cure the ultraviolet curable material 260.

At decision block 370, process 300 determines whether additional stencils 295 are to be used on the circuit substrate 220, for example by referencing a lookup table 216 or recipe for fabricating a particular circuit board. If more stencils 295 are to be used, then execution of process 300 loops back to block 320 and iterates. For example, one iteration may dispense and cure ink for labeling, and another iteration may dispense and cure solder mask.

Once each of the specified ultraviolet materials have been applied and cured, the process 300 ends. Processing of the circuit substrate 220 can continue with solder printing, pick-and-place population of electronic components, and heating via units 120, 125, and 130 as illustrated in FIG. 1 and discussed above.

Technology for processing a circuit substrate has been described. From the description, it will be appreciated that embodiments of the present technology overcome limitations of the prior art. Those skilled in the art will appreciate that the present technology is not limited to any specifically discussed application or implementation and that the embodiments described herein are illustrative and not restrictive. From the description of the exemplary embodiments, equivalents of the elements shown therein will suggest themselves to those skilled in the art, and ways of constructing other embodiments of the present technology will appear to practitioners of the art.

What is claimed is:

1. A system comprising:
a housing sized to accommodate a circuit substrate;
a bed that is disposed in the housing and that is configured for supporting the circuit substrate;
an applicator that is disposed in the housing;
an array of ultraviolet light emitting diodes disposed in the housing;
a positioning system operably coupled to the array of ultraviolet light emitting diodes and to the applicator; and
a controller comprising:
memory;
a processor that is operably coupled to the memory; and
processor executable instructions stored in the memory for performing the steps of:
causing the positioning system to move the applicator relative to the bed to dispense an ultraviolet curable material on the circuit substrate; and
causing the array of ultraviolet light emitting diodes to emit ultraviolet light to cure the dispensed ultraviolet curable material.

2. The system of claim 1, where the processor executable instructions stored in the memory are further for performing the step of moving the array of ultraviolet light emitting diodes relative to the bed while the array of ultraviolet light emitting diodes emit light.

3. The system of claim 1, wherein the positioning system is operative to create motion in two dimensions.

4. The system of claim 1, wherein the positioning system is operative to create motion in three dimensions.

5. The system of claim 1, wherein the circuit substrate comprises a circuit board.

6. The system of claim 1, wherein causing the positioning system to move the applicator relative to the bed to dispense the ultraviolet curable material on the circuit substrate comprises
squeegeeing the ultraviolet curable material at a stencil.

7. The system of claim 1, wherein the applicator comprises a squeegee.

8. A method comprising the steps of:
positioning a stencil against a substrate;
applying an ultraviolet curable material to the substrate by spreading the ultraviolet curable material on the stencil; and
curing the spread ultraviolet curable material in response to illuminating the spread ultraviolet curable material with light emitted from an array of light emitting diodes.

9. The method of claim 8, wherein illuminating the spread ultraviolet curable material with light emitted from the array of light emitting diodes comprises moving the array of light emitting diodes in one dimension while the array of light emitting diodes emits ultraviolet light.

10. The method of claim 8, wherein illuminating the spread ultraviolet curable material with light emitted from the array of light emitting diodes comprises moving the array of light emitting diodes in two dimensions while the array of light emitting diodes emits ultraviolet light.

11. The method of claim 8, further comprising the step of lifting the positioned stencil from the substrate after the applying step and before the curing step.

12. The method of claim 8, wherein the ultraviolet curable material comprises solder mask.

13. The method of claim 8, wherein the ultraviolet curable material comprises ink.

14. The method of claim 8, wherein the positioning step comprises moving the stencil with a computer-controlled positioning system,
wherein the applying step comprises moving a squeegee with the computer-controlled positioning system, and
wherein the curing step comprises moving the array of light emitting diodes with the computer-controlled positioning system.

15. A system comprising:
a housing; and
a controller comprising:
memory;
a processor that is operably coupled to the memory; and
processor executable instructions stored in the memory for performing the steps of:
positioning a stencil adjacent a circuit substrate while the circuit substrate is disposed in the housing;
applying an ultraviolet curable material to the circuit substrate by spreading the ultraviolet curable material on the stencil while the circuit substrate is disposed in the housing; and
illuminating the spread ultraviolet curable material with light emitted from an array of light emitting diodes to cure the spread ultraviolet curable material while the circuit substrate is disposed in the housing.

16. The system of claim 15, wherein illuminating the spread ultraviolet curable material with light emitted from the array of light emitting diodes comprises moving the array of light emitting diodes in two dimensions while the array of light emitting diodes emits ultraviolet light.

17. The system of claim 15, wherein the ultraviolet curable material comprises solder mask.

18. The system of claim 15, wherein the ultraviolet curable material comprises ink.

19. The system of claim 15, wherein the positioning step comprises moving the stencil with a computer-controlled positioning system,
wherein the applying step comprises moving a squeegee with the computer-controlled positioning system, and
wherein the curing step comprises moving the array of light emitting diodes with the computer-controlled positioning system.

20. The system of claim 15, wherein the array of light emitting diodes comprises a two-dimensional array of light emitting diodes that is disposed in the housing.
